(19) United States
(12) Patent Application Publication
(10) Pub. No.: US 2023/0125395 A1
(43) Pub. Date: Apr. 27, 2023

(54) STACKED STRUCTURES WITH CAPACITIVE COUPLING CONNECTIONS

(71) Applicant: ADEIA SEMICONDUCTOR BONDING TECHNOLOGIES INC., San Jose, CA (US)

(72) Inventors: Guilian Gao, San Jose, CA (US); Gaius Gillman Fountain, JR., Yougsville, NC (US); Belgacem Haba, Saratoga, CA (US)

(21) Appl. No.: 18/050,010

(22) Filed: Oct. 26, 2022

Related U.S. Application Data
(60) Provisional application No. 63/272,636, filed on Oct. 27, 2021.

(51) Int. Cl. H01L 23/00; H01L 23/48

(52) U.S. Cl. CPC H01L 24/08; H01L 23/481; H01L 24/80; H01L 2224/08145; H01L 2224/80379

(57) ABSTRACT

A multi-die electronic apparatus is disclosed. The multi-die electronic apparatus can comprise a first die comprising first communication pads, the first die having a first device surface including first devices, and a first back surface opposite the first device surface. A second die can include second communication pads, the second die having a second device surface including second devices, and a second back surface opposite the first device surface. The first and second dies can be vertically stacked with the second back surface facing the first device surface. At least one of the first communication pads can communicate a non-noise signal capacitively with at least one of the second communication pads.

### RELATED APPLICATIONS

This application claims the priority benefit of U.S. Provisional Patent Application 63/272,636 filed on Oct. 27, 2021, entitled “STACKED STRUCTURES WITH CAPACITIVE COUPLING CONNECTIONS,” which is incorporated by reference herein in its entirety.

### BACKGROUND

### Field

The field relates to stacked structures with capacitive coupling connections.

### Description of the Related Art

Multiple semiconductor elements (such as integrated device dies) may be stacked on top of one another in various applications, such as processors, high bandwidth memory (HBM) devices, or other devices that utilize vertical integration. The stacked elements can electrically communicate with one another. Signals and power can be transferred through the dies by way of through substrate vias (TSVs). Typically, direct electrical connections, such as direct bonds or solder bonds, are used to provide electrical communication between vertically adjacent dies.

### SUMMARY OF THE INVENTION

In one embodiment, a multi-die electronic apparatus can include: a first die comprising first communication pads, the first die having a first device surface including first devices, and a first back surface opposite the first device surface; a second die comprising second communication pads, the second die having a second device surface including second devices, and a second back surface opposite the first device surface; wherein the first and second dies are vertically stacked with the second back surface facing the first device surface, and at least one of the first communication pads communicates a non-noise signal capacitively with at least one of the second communication pads.

In some embodiments, the first die and the second die are directly bonded to one another. In some embodiments, the first die includes an insulating first bonding layer over the first device surface, the first bonding layer defining a first front surface of the first die, and the second die includes an insulating second bonding layer over the second back surface, the second bonding layer defining a second rear surface of the second die, the first and second bonding layers being directly bonded to one another without an intervening adhesive. In some embodiments, the first die further comprises a plurality of metallization levels between the first device surface and the first front surface, and the second die further comprises a plurality of second metallization layers between the second device surface and the second front surface. In some embodiments, the at least one first communication pad is proximate the first device surface and the at least one second communication pad is proximate the second device surface, wherein the at least one first communication pad communicates capacitively with the at least one second communication pad through a bulk semiconductor material of the second die. In some embodiments, the bulk semiconductor material of the second die has a thickness of less than about 10 μm. In some embodiments, the bulk semiconductor material of the second die has a thickness of less than about 5 μm. In some embodiments, the bulk semiconductor material of the second die has a thickness of less than about 3 μm. In some embodiments, the bulk semiconductor material of the second die has a thickness of less than about 2 μm.

In some embodiments, the at least one first communication pad additionally communicates capacitively with the at least one second communication pad through the first and second bonding layers. In some embodiments, the first bonding layer comprises a field bonding layer material between first communication pads and a first capacitive communication tuning dielectric material over the at least one first communication pad, such that the at least one first communication pad additionally communicates capacitively with the at least one second communication pad through the first capacitive communication tuning dielectric material. In some embodiments, the apparatus can include a second capacitive communication tuning dielectric over the at least one second communication pad, such that the at least one first communication pad additionally communicates capacitively with the at least one second communication pad through the first and second capacitive communication tuning dielectric materials. In some embodiments, no active devices are positioned between the at least one first communication pad and the at least one second communication pad. In some embodiments, no metal routing is positioned between the at least one first communication pad and the at least one second communication pad. In some embodiments, the first die and the second die are directly hybrid bonded to one another, wherein respective contact pads of the first and second dies directly contact one another at a bond interface to provide at least one of a power and ground connection between the first and second dies. In some embodiments, low frequency signal pads of the first and second communication pads directly contact one another at the bond interface, and the at least one first communication pad and the least one second communication pad comprise high frequency signal pads.

In some embodiments, the apparatus can include a third die comprising third communication pads, the third die having a third device surface including third devices, and a third back surface opposite the third device surface, wherein the second and third dies are vertically stacked with the third back surface facing the second device surface, and at least one of the third communication pads capacitively communicates with at least one of the second communication pads. In some embodiments, the at least one of the first communication pads communicates capacitively with a first pad of the at least one of the second communication pads, and wherein a second pad of the at least one of the second communication pads communicates capacitively with the at least one of the third communication pads. In some embodiments, capacitively coupled communications pads are arranged in a butterfly differential signaling scheme to minimize crosstalk among high frequency channels. In some embodiments, the first devices comprise active devices having at least one transistor. In some embodiments, the first devices comprise a passive device. In some embodiments, the passive device comprises an antenna.

In another embodiment, an electronic apparatus can include: a first die; a second die stacked on the first die; and a third die stacked on the second die; wherein the first and second dies are configured to communicate non-noise signals capacitively; and the second and third die are configured to communicate signals capacitively.

In some embodiments, the first, second, and third dies comprise integrated circuits. In some embodiments, at least one of the first, second, and third dies comprises an interposer. In some embodiments, the second die is directly bonded to the first die. In some embodiments, the third die is directly bonded to the second die. In some embodiments, the first die and the second die are directly hybrid bonded to one another, wherein ground and power pads of the first and second dies directly contact one another at a first bond interface between the first and second dies. In some embodiments, the first and second dies are attached to one another face-to-back, and the second and third dies are attached to one another face-to-back. In some embodiments, the first and second dies are configured to capacitively communicate signals between first and second signal pads, wherein a bulk semiconductor layer of the second die physically intervenes between the first and second signal pads. In some embodiments, the second and third dies are configured to capacitively communicate signals between second and third signal pads, wherein a bulk semiconductor layer of the third die physically intervenes between the second and third signal pads.

In another embodiment, a stack of dies can include: a first die comprising first communication pads; and a second die vertically stacked with the first die, the second die comprising second communication pads; wherein at least one of the first communication pads communicates a non-noise signal capacitively with at least one of the second communication pads with a semiconductor layer intervening between the at least one first communication pad and the at least one second communication pad.

In some embodiments, the first and second dies are stacked with a front surface of the first die facing a back surface of the second die, and the semiconductor layer comprises a bulk substrate of the second die. In some embodiments, the stack can include a third die stacked on the second die with a front surface of the second die facing a back surface of the third die, the third die comprising third communication pads, at least one of the third communication pads communicating capacitively with at least one of the second communication pads with a bulk substrate of the third die intervening between the at least one third communication pad and the at least one second communication pad. In some embodiments, the second die is directly bonded to the first die. In some embodiments, the second die is directly hybrid bonded to the first die, wherein at least ground and power pads of the first and second dies are directly bonded for conductive communication therebetween. In some embodiments, the stack can include at least one through substrate via (TSV) extending through the first die or the second die.

In another embodiment, an apparatus can include: a semiconductor device die; a first communication pad over a device surface of the semiconductor device die; a second communication pad over a back surface of the semiconductor device die such that an intervening portion of the semiconductor device die is disposed between the first communication pad and the second communication pad, the second communication pad configured to connect to an external signal pathway; and a capacitive coupling pathway through the first communication pad, the intervening portion of the semiconductor device die, and the second communication pad.

In some embodiments, the apparatus can include a first bonding layer over the device side of the semiconductor device die and a second bonding layer over the back surface of the semiconductor device die, the first communication pad at least partially embedded in the first bonding layer and the second communication pad at least partially embedded in the second bonding layer. In some embodiments, the apparatus can include a second device die bonded to the first semiconductor device die.

In another embodiment, a method can include: vertically stacking a second die vertically over a first die, the first die comprising first communication pads and the second die comprising second communication pads, wherein at least one of the first communication pads communicates a non-noise signal capacitively with at least one of the second communication pads with a semiconductor layer intervening between the at least one first communication pad and the at least one second communication pad.

In some embodiments, the method can include directly bonding a first bonding layer of the first die to a second bonding layer of the second die without an intervening adhesive. In some embodiments, the method can include directly bonding a first contact pad of the first die to a second contact pad of the second die without an intervening adhesive, the bonded first and second contact pads providing at least one of a power and ground connection between the first and second dies. In some embodiments, the method can include stacking a rear side of the second die over a front side of the first die.

In another embodiment, a method can include: providing a first die comprising first communication pads, the first die having a first device surface including first devices, and a first back surface opposite the first device surface; providing a second die comprising second communication pads, the second die having a second device surface including second devices, and a second back surface opposite the first device surface; and vertically stacking the first and second dies such that the second back surface faces the first device surface, and such that at least one of the first communication pads communicates a non-noise signal capacitively with at least one of the second communication pads.

In some embodiments, the method can include directly bonding a first bonding layer of the first die to a second bonding layer of the second die without an intervening adhesive. In some embodiments, the method can include directly bonding a first contact pad of the first die to a second contact pad of the second die without an intervening adhesive, the bonded first and second contact pads providing at least one of a power and ground connection between the first and second dies.

In another embodiment, a method can include: vertically stacking a second die on a first die, the first die comprising first communication pads and the second die comprising second communication pads, such that at least one of the first communication pads communicates a non-noise signal capacitively with at least one of the second communication pads with a semiconductor layer intervening between the at least one first communication pad and the at least one second communication pad.

In some embodiments, the method can include directly bonding a first bonding layer of the first die to a second bonding layer of the second die without an intervening adhesive. In some embodiments, the method can include directly bonding a first contact pad of the first die to a second contact pad of the second die without an intervening adhesive, the bonded first and second contact pads providing at least one of a power and ground connection between the first and second dies.

### BRIEF DESCRIPTION OF THE DRAWINGS

FIG. 1 is an example of integrated dies comprising a capacitive electrical pathway.

FIG. 2A is a schematic side sectional view of an integrated device die comprising a capacitive electrical pathway therethrough.

FIG. 2B is a schematic side sectional view of a stacked structure that provides a capacitive coupling connection through at least a portion of a thickness of a first device die.

FIG. 3 is a schematic side sectional view of a stacked structure that includes two stacked dies including a capacitive coupling connection therebetween.

FIG. 4 is a schematic side sectional view of a stacked structure that includes three stacked dies including a capacitive coupling connection therebetween.

### DETAILED DESCRIPTION

Stacked device dies are typically electrically connected to one another by way of direct electrical connections. For example, contact pads of one die are electrically connected to contact pads of a vertically adjacent die by way of any number of bonding methods, such as direct hybrid bonding, solder bonding, thermocompression bonding (TCB), etc. Direct electrical connections (or conductive connections) typically utilize numerous traces across multiple metallization layers, which can be complicated to pattern and deposit. Moreover, providing conductive metallic connections between opposing contact pads can be challenging when bonding fine pitch pads due to misalignment error. Contact pads for direct connections may also be relatively large so as to provide improved alignment and contact, which may be incompatible with dies that utilize very fine pitch and pad size. Accordingly, there remains a continuing need for improved electrical interconnections between stacked dies.

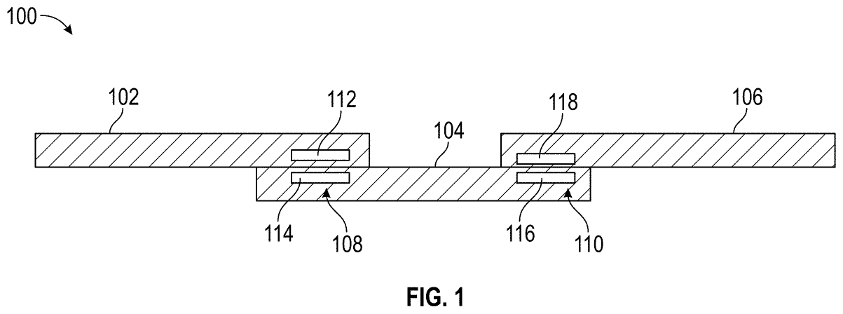

FIG. 1 illustrates an example in which a first die 102 is provided over and partially overlaps an underlying second die 104. A third die 106 is provided over and partially overlaps the second die 104. In FIG. 1, the first die 102 is electrically connected to the second die 104 by way of a first capacitive coupling connection 108, and the second die 104 is electrically connected to the third die 106 by way of a second capacitive coupling connection 110. In the illustrated example, the first die 102 can serve as or comprise a transmitting (Tx) 112 device and the second die 104 can serve as or comprise a receiving (Rx) device 114 that receives a signal from the Tx device 112 of the first die 102. Similarly, the second die 104 can serve as or comprise a Tx device 116 that transmits a signal to a Rx device 118 of the third die 106.

Beneficially, capacitive coupling connections can obviate the use of complex routing traces used for direct connection between dies, and can increase the bandwidth of the system. The chip size can be reduced (as can the size of the Tx and Rx devices), and testing can be improved. Moreover, smaller communication pads (which can serve as the plates of the capacitive connection) can be used as compared to contact pads used for direct electrical connections. Accordingly, there remains a continuing need for improved capacitive connections.

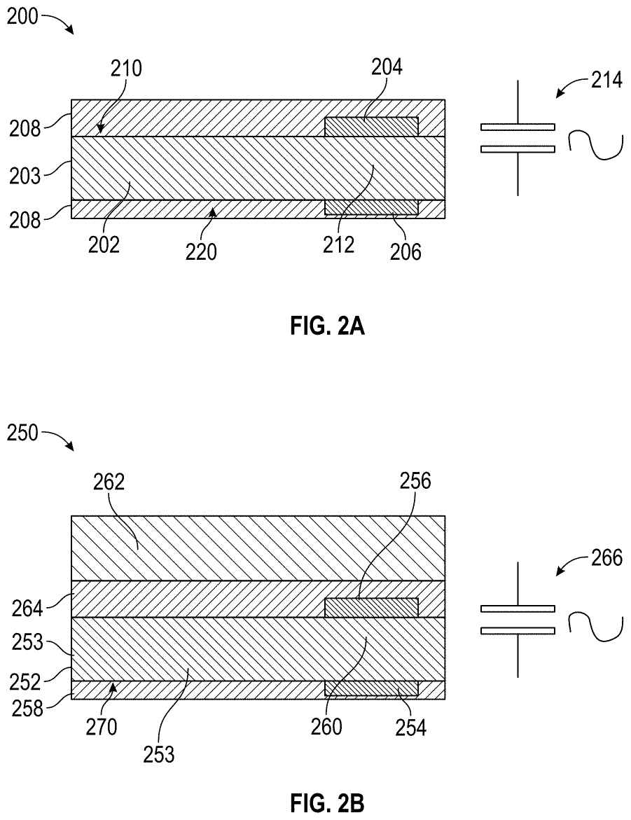

FIG. 2A illustrates a schematic side sectional view of an integrated device die 200 that includes a capacitive electrical pathway therethrough. As shown in FIG. 2A, the semiconductor die 202 can include a first communication pad 204 over a device side or surface 210 of the semiconductor device die 202 (e.g., over device surface of device portion 203) and a second communication pad 206 over a back surface 220 of the semiconductor device die 202 (e.g., over back surface of the device portion 203). The semiconductor device die 202 can include a device portion 203. The device portion 203 can include one or more devices (such as active circuitry, e.g., one or more transistors) formed or patterned therein. In the illustrated embodiment, respective insulating layers 208 can be provided over the device surface 210 and the back surface 220, and can include one or more layers with patterned metallization. For example, the insulating layer 208 can comprise a dielectric material, such as silicon oxide, silicon nitride, etc. The first and/or second communication pads 204, 206 can be completely embedded in the insulating layer(s) 208 in various embodiments. In other embodiments, the first and/or second communication pads 204, 206 can be deposited on the device and/or back surfaces 210, 220 (or onto a passivation layer disposed on the semiconductor surface).

One or more devices can be disposed at or near the device surface 210. For example, the devices can comprise active circuitry (e.g., transistor(s)) and/or passive devices (such as an antenna). In various embodiments, the device(s) can be disposed closer to the device surface 210 than to the back surface 220. The back surface 220 may be devoid of devices (e.g., devoid of active circuitry, and/or devoid of passive devices) in some embodiments. In other embodiments, one or more devices may be disposed at or near the back surface 220.

As shown, an intervening portion of the semiconductor device die 202 (for example, the device portion 203) can disposed between the first communication pad 204 and the second communication pad 206. A capacitive coupling pathway 214 can pass through the first communication pad 204, the intervening portion of the semiconductor device die 202, and the second communication pad 206 to provide a capacitive pathway 214 through the bulk semiconductor material 212 (e.g., bulk silicon) of the die. The capacitive pathway 214 can comprise non-noise signals excluding any incidental noise due to capacitive coupling of adjacent pads as parasitic capacitance can exists between adjacent pads. The capacitive pathway between 214 between through the first communication pad 204 and the second communication pad 206 can contain the signal transferred from the first communication pad 204 and received by the second communication pad 206, excluding extraneous signals from adjacent and/or nearby devices. In some embodiments, portion(s) of one or both of the upper and lower insulating layer(s) 208 may also intervene between the first and second communication pads 204, 206. Thus, in various embodiments, the semiconductor portion 212 of the die can serve as the insulator for the capacitive pathway defined between the first and second communication pads 204, 206. Portions of the upper and lower insulating layer(s) 208 may also serve as the intervening insulator for the capacitive pathway.

FIG. 2B is a schematic side sectional view of a stacked structure 250 that provides a capacitive coupling connection 266 through at least a portion of a thickness of a first device die 252. As shown in FIG. 2B, a second device die 262 can be stacked on the first device die 252. In the illustrated embodiment, the second die 262 can be direct hybrid bonded to the first die 252 without an intervening adhesive. For example, one or both of the first and second dies 252, 262 can comprise a bonding layer(s) 264 that can facilitate direct bonding between the dies as explained below. In other embodiments, the second die 262 can be bonded to the first die 252 using other techniques, such as TCB or solder bonding.

As shown in FIG. 2B, a first communication pad 254 can be provided at or near a lower surface 270 of the first die 252. The first die 252 can include a device portion 253. In the illustrated embodiment, the first communication pad 254 can be provided within an insulating layer 258 (such as a back-end-of-line, or BEOL) disposed over the front surface 253 of the semiconductor material. A second communication pad 256 can be provided in the bonding layer 264 between the dies 252, 262. The second communication pad 256 can be provided in a bonding layer 264 deposited on the first die 252, or on a bonding layer 264 provided on the second die 262. As explained herein, the bonding layer 264 can comprise one or multiple layers, including one or multiple nonconductive (e.g., dielectric) layers (such as silicon oxide layers) with metallization patterned and at least partially embedded therein. In multi-layer bonding layers, the uppermost layer can comprise the bonding surface configured for direct bonding to an opposing die. As shown in FIG. 2B, at least a portion of the bulk semiconductor material 260 comprising a semiconductor layer can be disposed between the first and second communication pads 254, 256. Thus, in FIG. 2B, a portion of the bulk semiconductor material 260 can serve as the insulating field of the capacitive coupling between the first and second pads 254, 256 (which can serve as the plates of the capacitive connection).

In FIG. 2B, the dies 252, 262 can be bonded in a front-to-front, front-to-back, or back-to-back arrangement. The use of direct bonding to connect the first and second dies 252, 262 can beneficially provide a precise alignment between the dies while avoiding problems associated with thermal expansion, vibration, and the like. In some embodiments, at least a portion of the material or gap between the communication pads can be removed and filled with a capacitive communication tuning dielectric material that can improve the capacitive performance of the stacked structure. The capacitive tuning dielectric material can comprise a filling material having a higher dielectric constant which can yield lower losses as compared with a semiconductor material such as silicon. Suitable materials for the capacitive tuning dielectric material can include silicon nitride (Sn₃N₄), aluminum oxide (Al₂O₃) tantalum oxide (Ta₂O₅), titanium oxide (TiO₂), zirconium oxdie (ZrO₂) and hafnium oxide (HfO₂). The silicon material between the pads can also be depleted to act as a dielectric material.

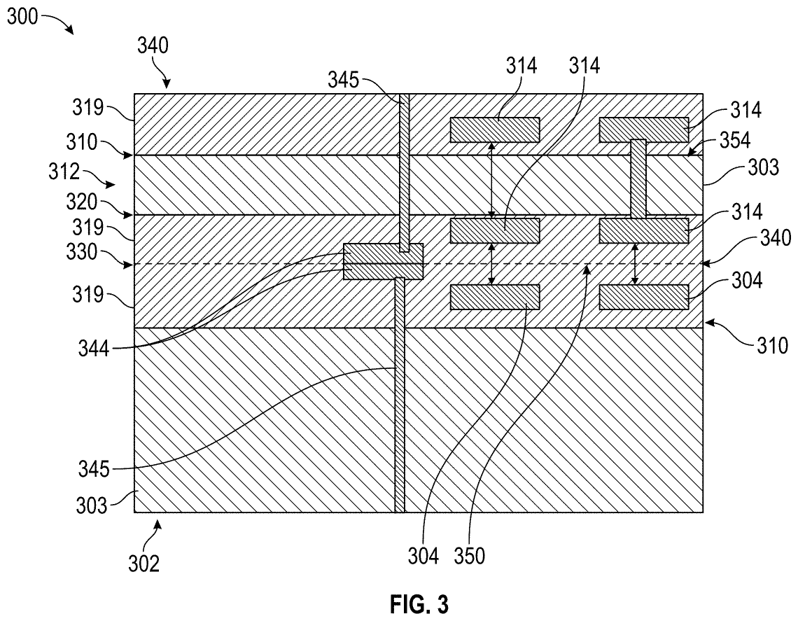

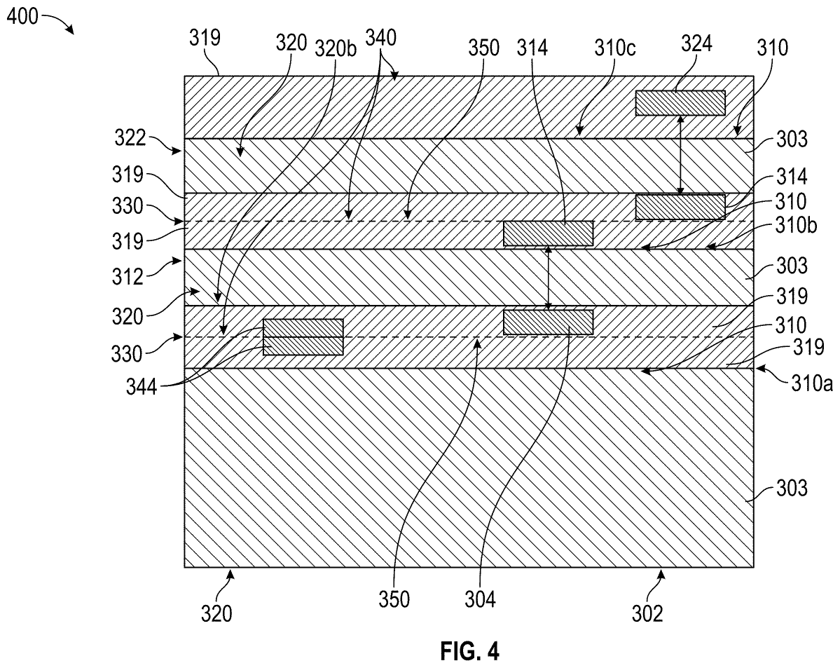

FIG. 3 is a schematic side sectional view of a stacked structure 300 that includes two stacked dies including a capacitive coupling connection therebetween. FIG. 4 is a schematic side sectional view of a stacked structure 400 that includes three stacked dies including a capacitive coupling connection therebetween. Although two and three dies are shown in FIGS. 3 and 4, respectively, it should be appreciated that any suitable number of dies can be stacked in accordance with the embodiments disclosed herein.

In FIGS. 3 and 4, a first die 302 and can include first communication pads 304, a second die 312 can include second communication pads 314, and a third die 322 can include third communication pads 324. Each die can have a device portion 303. Each die can have a device surface 310 including devices at or near the device surfaces 310, and a back surface 320 opposite the device surface. The device dies can comprise any suitable type of device die, such as a processor die, memory die, passive device die, etc. In some embodiments, the die(s) can comprise an interposer, which may or may not include active circuitry. As explained above, one or more active devices (e.g., active circuitry including transistor(s)) can be disposed at or near the device surface(s) 310. Additionally or alternatively, one or more passive devices (e.g., antenna(s)) can be provided at or near the device surface(s)) 310. The device(s) can be disposed nearer to the device surface 310 than to the back surface 320 of the associated die. In some embodiments, the back surface(s) 320 can be devoid of active devices and/or passive devices. In other embodiments, one or more devices may be provided at or near the back surface(s) 320.

As shown, the first and second dies 302, 312 are vertically stacked with the second back surface 320b facing the first device surface 310a. At least one of the first communication pads 304 of the first die 302 communicates capacitively with at least one of the second communication pads 314 of the second die 312. The second and third dies 312, 322 can be vertically stacked with the back surface 320c of the third die 322 facing the device surface 310b of the second die 312. At least one of the third communication pads 324 can capacitively communicate with at least one of the second communication pads 314. At least one of the first, second, and third communication pads 304, 314, 324 can be configured to connect to an external signal pathway to provide electrical communication with an external signal.

As shown in FIGS. 3 and 4, at least one semiconductor layer can be disposed between first and second communication pads 304, 314. For example, in FIG. 3, device die 312 can intervene between opposing communication pads. In FIG. 4, device dies 312 and 322 can be disposed between communication pads so as to define at least a portion of the capacitive pathway. As explained herein, the capacitive pathway can be used to convey signals through the stack, which can be done at high speeds and high bandwidth. The use of the capacitive pathway for signal transfer can obviate the use of a significant portion of metal patterning which would be used in conductive connections for signal lines.

In the illustrated embodiments, device dies can be directly bonded to one another without an intervening adhesive. In some embodiments, a direct hybrid bond can be used to connect opposing dies. For example, as shown in FIGS. 3 and 4, device dies 302 and 312 can be direct hybrid bonded such that insulating bonding layers are directly bonded without an adhesive and opposing contact pads are directly bonded without an adhesive. In some embodiments, it may be desirable to use a direct electrical connection (e.g., a conductive connection) for delivering power and/or ground to one or more dies of the stack by way of the directly bonded contact pads and vias 345. In some embodiments, low speed signals may also be delivered to one or more dies of the stack by way of the directly bonded contact pads and vias. For example, low frequency signal pads 344 (e.g., pads for signals at frequencies of less than 10 kHz, less than 5 kHz, or less than 1 kHz; also mentioned herein as “contact pads”) can directly contact one another at the bond interface 330, and the at least one first communication pad 304 and the least one second communication pad 314 comprise high frequency signal pads capacitively coupled together. Conductive connections may be desirable for power distribution, for example, since it may be challenging to deliver power by way of a capacitive connection.

In some embodiments, the direct bond between opposing dies may only include direct nonconductive bonds without any direct conductive connections between pads. For example, as shown in FIG. 4, the direct bond between device dies 312 and 322 may comprise a nonconductive bond without direct conductive connections between pads. In such embodiments, power and/or ground can be distributed to the die(s) by way of other connection methods such as wire bonds 354. Skilled artisans will understand that many combinations of hybrid and nonconductive bonds may be used. In still other embodiments, one or more of the dies may be bonded with an adhesive or using other bonding techniques.

The bonding layer 319 can comprise one or multiple insulating layers 318 with one or a plurality of metallization levels provided therein. The uppermost layer (if multiple layers are used) can be prepared for direct bonding. Thus, the die(s) can further comprise a plurality of metallization levels between the device surface and the front surface 340 (which may be defined by the bonding layer over the device surface of the semiconductor portions of the dies), and between the back surface and the rear surface 350 (which may be defined by the bonding layer over the back surface of the semiconductor portions of the dies). At least one first communication pad can be proximate to the device surface (e.g., closer to the device surface than the back surface) of a first die and at least one second communication pad can be proximate the second device surface (e.g., closer to the device surface than the back surface). The at least one first communication pad 304 can communicate capacitively with the at least one second communication pad 314 through a bulk semiconductor material of the second die 212. The at least one first communication pad 304 can additionally communicate capacitively with the at least one second communication pad 314 through portions of the bonding layers 330. In various embodiments, the bulk semiconductor material of the die(s) can have a thickness of less than about 10 μm, less than about 5 μm, less than about 3 μm, or less than about 2 μm.

In some embodiments, the bonding layer(s) 330 can comprise a field bonding layer material between first communication pads and a first capacitive communication tuning dielectric material over the at least one first communication pad, such that the at least one first communication pad additionally communicates capacitively with the at least one second communication pad through the first capacitive communication tuning dielectric material. A second capacitive communication tuning dielectric can be provided over the at least one second communication pad, such that the at least one first communication pad additionally communicates capacitively with the at least one second communication pad through the first and second capacitive communication tuning dielectric materials.

In various embodiments, no active devices are positioned between the at least one first communication pad and the at least one second communication pad. In some embodiments, no metal routing is positioned between the at least one first communication pad and the at least one second communication pad.

In various embodiments, the capacitively coupled communications pads can be arranged in a butterfly differential signaling scheme to minimize crosstalk among high frequency channels. Skilled artisans would appreciate that other arrangements may be suitable.

Beneficially, the disclosed embodiments allow capacitive coupling through a stack of multiple dies (or across a single die), which provides a robust electrical connection that can enable high frequency signal transmission. The disclosed embodiments are easy to scale and can be provided in any suitable number of device die layers in the stack. The location of the communication pads can be selected based on the proximity to the mating pad, the thickness of the semiconductor portion, etc. As explained above, the capacitive coupling mechanism can obviate the use of metallic patterning for direct connections for at least some signal lines.

### Examples of Direct Bonding Methods and Directly Bonded Structures

Various embodiments disclosed herein relate to directly bonded structures in which two elements can be directly bonded to one another without an intervening adhesive. Two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a routing layer or a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of hybrid bonding techniques, such as Direct Bond Interconnect, or DBI®, available commercially from Adeia of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented along the crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A multi-die electronic apparatus comprising:
a first die comprising first communication pads, the first die having a first device surface including first devices, and a first back surface opposite the first device surface;
a second die comprising second communication pads, the second die having a second device surface including second devices, and a second back surface opposite the first device surface;
wherein the first and second dies are vertically stacked with the second back surface facing the first device surface, and
at least one of the first communication pads communicates a non-noise signal capacitively with at least one of the second communication pads.

2. The apparatus of claim 1, wherein the first die and the second die are directly bonded to one another.

3. (canceled)

4. (canceled)

5. The apparatus of claim 2, wherein the at least one first communication pad is proximate the first device surface and the at least one second communication pad is proximate the second device surface, wherein the at least one first communication pad communicates capacitively with the at least one second communication pad through a bulk semiconductor material of the second die.

6. (canceled)

7. (canceled)

8. (canceled)

9. (canceled)

10. The apparatus of claim 5, wherein the at least one first communication pad additionally communicates capacitively with the at least one second communication pad through the first and second bonding layers.

11. The apparatus of claim 5, wherein the first bonding layer comprises a field bonding layer material between first communication pads and a first capacitive communication tuning dielectric material over the at least one first communication pad, such that the at least one first communication pad additionally communicates capacitively with the at least one second communication pad through the first capacitive communication tuning dielectric material.

12. The apparatus of claim 11, further comprising a second capacitive communication tuning dielectric over the at least one second communication pad, such that the at least one first communication pad additionally communicates capacitively with the at least one second communication pad through the first and second capacitive communication tuning dielectric materials.

13. (canceled)

14. (canceled)

15. The apparatus of claim 1, wherein the first die and the second die are directly hybrid bonded to one another, wherein respective contact pads of the first and second dies directly contact one another at a bond interface to provide at least one of a power and ground connection between the first and second dies.

16. (canceled)

17. The apparatus of claim 1, further comprising a third die comprising third communication pads, the third die having a third device surface including third devices, and a third back surface opposite the third device surface, wherein the second and third dies are vertically stacked with the third back surface facing the second device surface, and at least one of the third communication pads capacitively communicates with at least one of the second communication pads.

18. The apparatus of claim 17, wherein the at least one of the first communication pads communicates capacitively with a first pad of the at least one of the second communication pads, and wherein a second pad of the at least one of the second communication pads communicates capacitively with the at least one of the third communication pads.

19. (canceled)

20. (canceled)

21. (canceled)

22. (canceled)

23. An electronic apparatus, comprising:
a first die;
a second die stacked on the first die; and
a third die stacked on the second die;
wherein the first and second dies are configured to communicate non-noise signals capacitively; and
the second and third die are configured to communicate non-noise signals capacitively.

24. (canceled)

25. (canceled)

26. The apparatus of claim 23, wherein the second die is directly bonded to the first die.

27. The apparatus of claim 23, wherein the third die is directly bonded to the second die.

28. The apparatus of claim 23, wherein the first die and the second die are directly hybrid bonded to one another, wherein ground and power pads of the first and second dies directly contact one another at a first bond interface between the first and second dies.

29. (canceled)

30. The apparatus of claim 23, wherein the first and second dies are configured to capacitively communicate signals between first and second signal pads, wherein a bulk semiconductor layer of the second die physically intervenes between the first and second signal pads.

31. The apparatus of claim 23, wherein the second and third dies are configured to capacitively communicate signals between second and third signal pads, wherein a bulk semiconductor layer of the third die physically intervenes between the second and third signal pads.

32. A stack of dies, comprising:
a first die comprising first communication pads; and
a second die vertically stacked with the first die, the second die comprising second communication pads;
wherein at least one of the first communication pads communicates a signal capacitively with at least one of the second communication pads with a semiconductor layer intervening between the at least one first communication pad and the at least one second communication pad.

33. The stack of dies of claim 32, wherein the first and second dies are stacked with a front surface of the first die facing a back surface of the second die, and the semiconductor layer comprises a bulk substrate of the second die.

34. The stack of dies of claim 33, further comprising a third die stacked on the second die with a front surface of the second die facing a back surface of the third die, the third die comprising third communication pads, at least one of the third communication pads communicating capacitively with at least one of the second communication pads with a bulk substrate of the third die intervening between the at least one third communication pad and the at least one second communication pad.

35. The stack of dies of claim 32, wherein the second die is directly bonded to the first die.

36. The stack of dies of claim 35, wherein the second die is directly hybrid bonded to the first die, wherein at least ground and power pads of the first and second dies are directly bonded for conductive communication therebetween.

37.-52. (canceled)
